(19) United States
(12) Patent Application Publication
(10) Pub. No.: US 2013/0118576 A1
(43) Pub. Date: May 16, 2013

(54) COVERING LAYER FOR SOLAR CELL

(71) Applicant: SIKA TECHNOLOGY AG, Baar (CH)

(72) Inventors: Heinz Meier, Zurich (CH); Norman Blank, Ruschlikon (CH)

(73) Assignee: SIKA TECHNOLOGY AG, Saar (CH)

(21) Appl. No.: 13/732,835

(22) Filed: Jan. 2, 2013

Related U.S. Application Data
(63) Continuation of application No. PCT/EP2011/061158, filed on Jul. 1, 2011.

(30) Foreign Application Priority Data
Jul. 1, 2010 (EP) 10168106.2

(51) Int. Cl. H01L 31/0216; H01L 31/18

(52) U.S. Cl. CPC H01L 31/02167; H01L 31/18
USPC 136/256; 438/64

(57) ABSTRACT

A module is disclosed, which includes a carrier, at least one solar cell disposed on the carrier, and a covering layer that is applied to a side of the at least one solar cell facing away from the carrier. The covering layer includes side lugs, corner lugs, and notches, and wherein one notch each forms a side edge of a side lug or of a corner lug. The side lugs and corner lugs are divided by a corresponding fold line and are disposed on the side of the carrier facing away from the at least one solar cell. The side edges of the corresponding side lugs and corner lugs formed by a notch are in contact with one another.

### RELATED APPLICATIONS

This application claims priority as a continuation application under 35 U.S.C. §120 to PCT/EP2011/061158, which was filed as an International Application on Jul. 1, 2011 designating the U.S., and which claims priority to European Application No. 10168106.2 in Europe on Jul. 1, 2010. The entire contents of these applications are hereby incorporated by reference in their entireties.

### FIELD

The disclosure relates to a module, which includes a solar cell disposed on a carrier, and a covering layer, which faces away from the carrier.

### BACKGROUND INFORMATION

Solar modules with solar cells arranged on carriers can be covered with a covering layer in order to protect the solar cells from moisture and dirt.

For example, due to mechanical stresses and the effects of weather, the covering layer can be loosened from the carrier at the sides, whereupon moisture can penetrate between the covering layer and the carrier and damage the solar cells.

The stresses mentioned can be caused, for example, by horizontal and vertical shifting of solar cells and carrier relative to one another, for example, due to different thermal coefficients of linear expansion. Such stresses can occur, for example, during heating by intense insolation, because of heat production by the solar cells themselves, and at low outdoor temperatures.

Furthermore, the chemical and/or physical bond between the covering layer and the carrier can be exposed to external influences such as climate and UV radiation, which can result in the bond being damaged over time by these effects, for example, as a result of the covering layer being transparent to UV.

### SUMMARY

A module is disclosed comprising: a carrier; at least one solar cell disposed on the carrier; and a covering layer that is applied to a side of the at least one solar cell facing away from the carrier, wherein the covering layer includes side lugs, corner lugs, and notches, and wherein one notch forms a side edge of a side lug, another notch forms a side edge of a corner lug, and the side lugs and corner lugs are divided by a corresponding fold line and are disposed on a side of the carrier facing away from the at least one solar cell, and wherein the side edges of the side lugs and corner lugs formed by a notch are in contact with one another.

A module is disclosed comprising: a carrier; at least one solar cell arranged on the carrier; a covering layer, having side lugs and corner lugs, which is provided on a side of the solar cell facing away from the carrier, and wherein the side lugs and the corner lugs include a notch on one side edge of a side lug or on one side edge of a corner lug, and wherein the side lugs and the corner lugs are separated by a fold line and disposed on a side of the carrier facing away from the at least one solar cell, and wherein sides edges of side lugs and corner lugs formed by a notch are in contact with one another; and wherein the side lugs and the corner lugs are parts of the covering layer.

A method of covering at least one solar cell is disclosed, comprising: providing a carrier; disposing at least one solar cell on the carrier; and applying a covering layer to a side of the at least one solar cell facing away from the carrier, wherein the covering layer includes side lugs, corner lugs, and notches, and wherein one notch forms a side edge of a side lug, another notch forms a side edge of a corner lug, and the side lugs and corner lugs are divided by a corresponding fold line and are disposed on the side of the carrier facing away from the at least one solar cell, and wherein the side edges of the corresponding side lugs and corner lugs formed by a notch are in contact with one another.

### BRIEF DESCRIPTION OF THE DRAWINGS

Embodiments of the present disclosure will now be provided, by way of example only, and with reference to the following figures, in which:

FIG. 1 shows a cross section through a known module;

FIG. 2 shows a cross section through a module according to an exemplary embodiment;

FIG. 3 shows a cross section through a module according to another exemplary embodiment;

FIG. 4a shows a top view of a side of a carrier facing away from the solar cell in a module according to an exemplary embodiment, before applying the side lugs and corner lugs to the carrier;

FIG. 4b shows the module of FIGS. 4a according an exemplary embodiment, wherein a corner lug has been folded on the fold line and is located on the carrier;

FIG. 4c shows the module of FIGS. 4a and 4b after folding the side lugs on the corresponding fold line in accordance with an exemplary embodiment;

FIG. 5a shows a top view of a side of module of a carrier facing away from a solar cell in a module according to an exemplary embodiment;

FIG. 5b shows the module of FIG. 5a in accordance with an exemplary embodiment, after folding the side lug and the corner lugs over the corresponding fold lines.

FIG. 6a shows the side lugs and corner lugs of a module before application to a carrier in accordance with an exemplary embodiment;

FIG. 6b shows the module of FIG. 6a after folding the second side lug onto the first and subsequently folding the corner lug thereon in accordance with an exemplary embodiment;

FIG. 7a shows the module of FIG. 5a after folding the side lugs around the fold line in accordance with an exemplary embodiment; and

FIG. 7b shows the arrangement of the corner lug of the module as shown in FIG. 5c in accordance with an exemplary embodiment.

### DETAILED DESCRIPTION

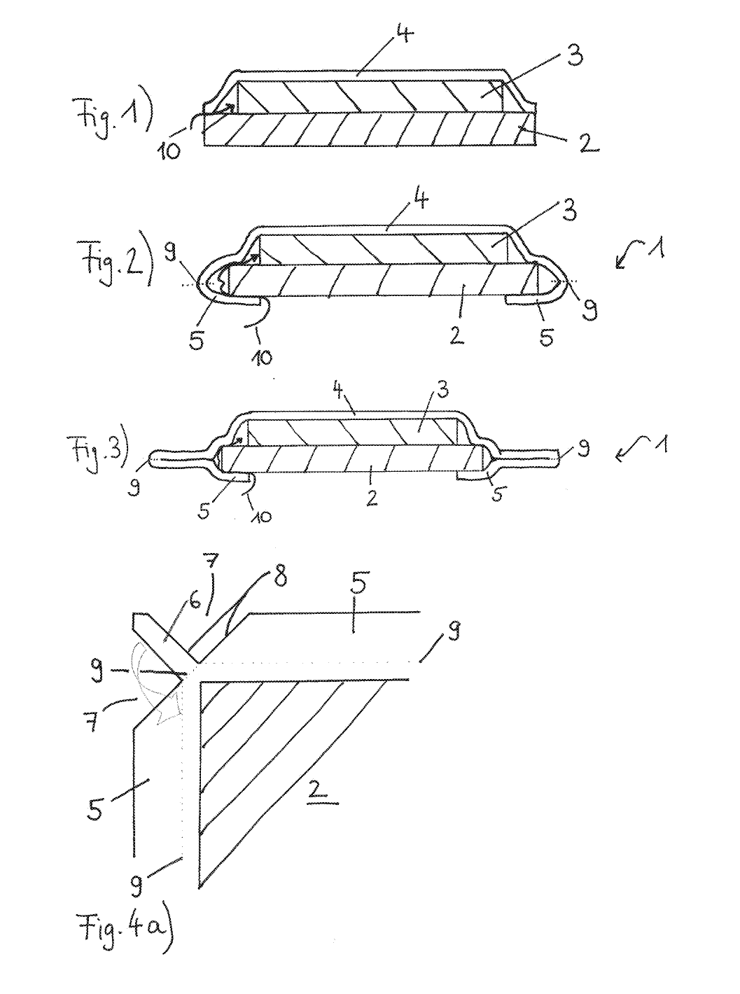

In FIG. 1, a cross section of a known module is represented, which exhibits a covering layer 4 that is applied over a solar cell 3 and is bonded with the carrier 2.

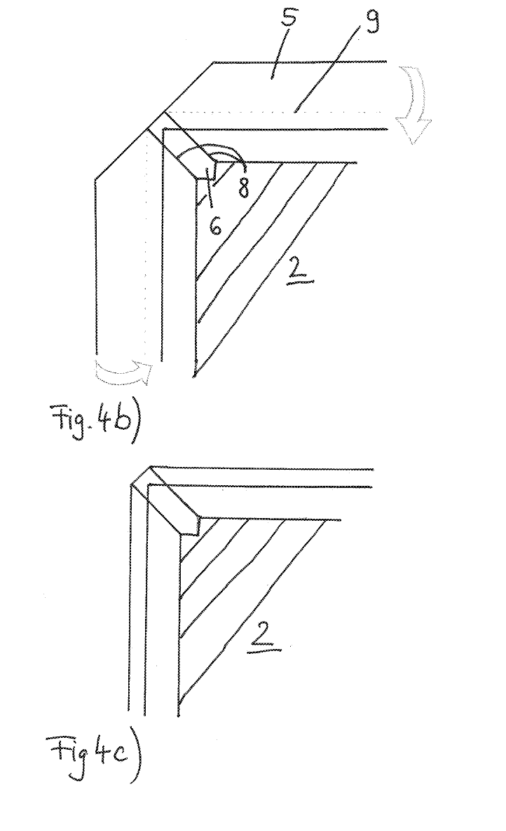

FIG. 2 shows a cross section of a module 1 according to an exemplary embodiment, in which the covering layer 4 can be disposed above side lugs 5 on the side of the carrier 2 facing away from the solar cell 3. FIG. 3 shows a variant of FIG. 2 in which the covering layer is folded laterally onto itself. For example, by folding the covering layer laterally onto itself, the sealing of the carrier and the solar cell with the covering layer can be relatively easier.

FIGS. 2 and 3 show, in comparison with FIG. 1, a substantially longer diffusion path for penetrating liquids 10. In the figures according to the discloser, in order to reach the solar cell 3, the penetrating liquid can overcome the contact between side lugs 5 and carrier 2 and the contact of the covering layer 4 with the side of the carrier facing the solar cell.

FIG. 4a shows a top view of the side of the carrier facing away from the solar cell in a module according to an exemplary embodiment, before applying the side lugs and the corner lugs to the carrier. In FIG. 4b, a corner lug 6 has already been folded on the fold line 9 and is located on the carrier 2. FIG. 4c shows the module after folding the side lugs on the corresponding fold lines. The side edges 8 of the side lugs 5 and of the corner lugs 6 formed by the notches 7 come, in FIG. 4c, to lie flush next to one another on the carrier and are thereby in contact with one another, which can protect them from the penetration of moisture in the area of the side edges between the covering layer and the side of the carrier facing away from the solar cell.

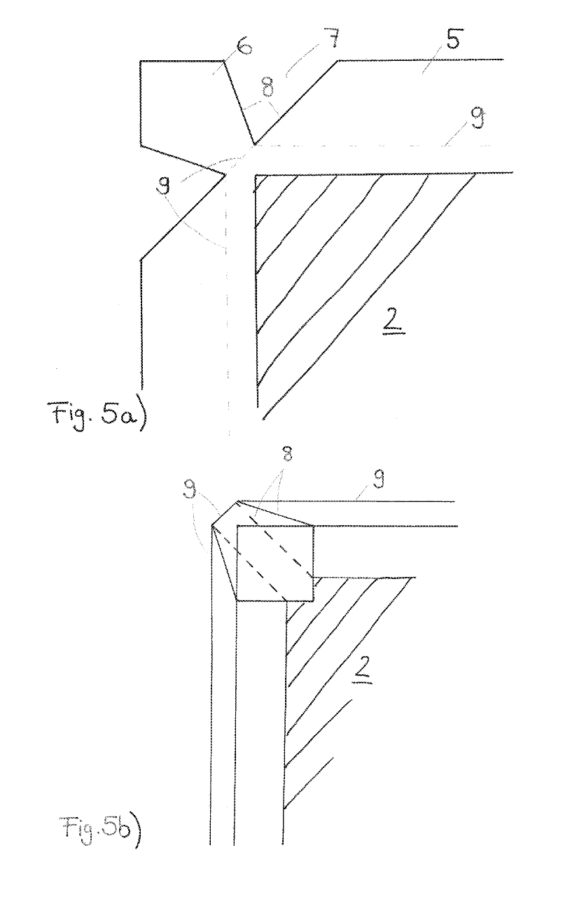

FIGS. 5a and 5b show an exemplary embodiment. FIG. 5a shows a top view of the side of the carrier facing away from the solar cell in a module according to an exemplary embodiment, before applying the side lugs and the corner lugs to the carrier. FIG. 5b shows the module after folding the side lugs and the corner lugs over the corresponding fold lines. For example, the side edges of the corner lugs can overlap the corresponding side edges of the adjacent side lugs, for example, along the total side edge of the side lugs. The overlap area can further increase in the diffusion path for liquid penetrating to the solar cell. For the reasons mentioned before, that the side edges of the side lugs can overlap the corresponding side edges of the adjacent corner lugs, for example, along the total side edge of the corner lugs.

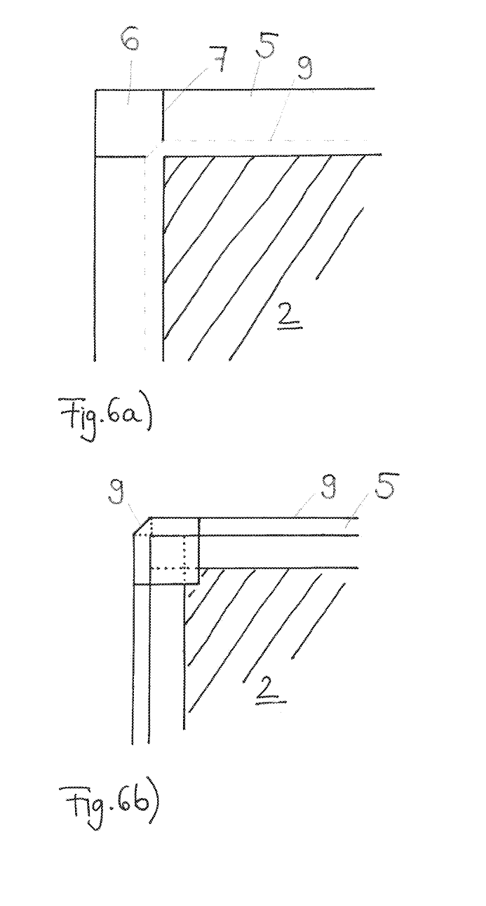

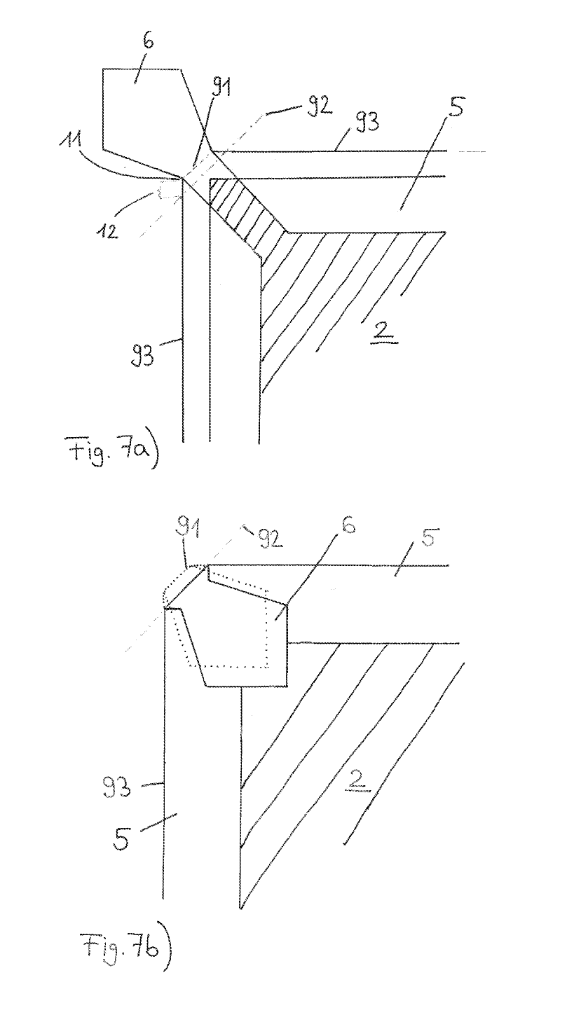

FIGS. 6a and 6b show a further exemplary embodiment. FIG. 6a also shows side lugs 5 and corner lugs 6 before application to the carrier 2. The notch 7 involves an actual incision in the covering layer up to the fold line 9 of the side and corner lugs, forming a notch without the removal of material from the covering layer and consequently forms the side edges 8 of the adjacent side and corner lugs. For example, the notch exhibits an angle of approximately 5° to 45°, measured from the fold line of the adjoining side edge and bounded by the two adjoining side edges 8. FIG. 6b shows the module after folding the second side lug onto the first and subsequently folding the corner lug thereon. Also, the corresponding side edges can be overlapped by the corner lugs here, for example, along the total side edge of the side lugs.

Another exemplary embodiment is shown in FIGS. 7a and 7b. FIG. 7a corresponds to FIG. 5a after folding the side lugs around the fold line 93. The broken fold line 91 shows the arrangement of the fold line of the corner lugs 6 used in FIG. 5b, while the fold line 92 of the corner lugs intersects the fold line 93 of the adjacent side lugs. For example, the fold line of the corner lugs intersects the fold line of the side lugs at a location that is approximately 3 mm to 15 mm away, measured from the point of contact of the side edges 8 of the corresponding side lugs 5 and corner lugs 6. The distance 12 therefore, for example, amounts to approximately 3 mm to 15 mm, as mentioned previously.

In FIG. 7b, the arrangement of the corner lugs shown in FIG. 5c is indicated by the dotted lines. The point of contact 11, at which the notch 7 meets the fold lines 9 or where the side edges 8 of the corresponding side and corner lugs converge, can be susceptible to penetrating liquid. By shifting the fold line of the corner lugs in the direction of the center point of the carrier, as is shown by shifting fold line 91 toward fold line 92, the diffusion path for penetrating liquid toward the solar cell can be thereby further increased.

Furthermore, for example, the fold lines 9 can exhibit a distance of at least 2 mm to 10 mm from carrier 2, which can be advantageous with respect to production engineering.

The covering layer 4 and the carrier 2, for example, the side lugs 5 and the corner lugs 6 and the side of the carrier 2 facing away from the solar cell 3, can be joined directly together. By “joined directly,” for example, it can be understood that no further layer or substance can be present between two materials and that the two materials can be directly connected to one another, for example, adhered to one another.

It can thereby result, for example, that in production, the direct bond can be achieved through the effect of heat, pressure, physical absorption, or of any other physical force. For example, that no chemical bond by means of glues is necessary, which has an advantageous effect on the production costs of the module 1.

There is, however, also the possibility of joining the covering layer 4 and the carrier, particularly the side lugs 5 and the corner lugs 6 and the side of the carrier 2 facing away from the solar cell 3, by means of an adhesive layer. An adhesive used in such an adhesive layer can, for example, be a contact adhesive and/or a hot melt adhesive. For example, an adhesive can help ensure a good bond and can also provide additional protection from the penetration of moisture.

Contact and hot melt adhesives, for example, which are generally known to the person skilled in the art and can be described in the CD Römpp Chemie Lexikon [Encyclopedia of Chemistry] (1995), Georg Thieme Verlag: Stuttgart, Version 1.0.

For example, such an adhesive involves an adhesive selected from the group consisting of ethylene/vinyl acetate copolymers (EVAs), crosslinkable thermoplastic elastomers on an olefin base, acrylate compounds, polyurethane polymers, and silane-terminated polymers.

Acrylate compounds can be, for example, acrylate compounds on an acrylic monomer base, especially based on acrylic and methacrylic acid esters.

The term “polyurethane polymer” can, for example, include all the polymers that can be manufactured according to the so-called diisocyanate polyadditions method. This also can include those polymers that can be approximately or entirely free of urethane groups. Examples of polyurethane polymers are polyether polyurethane, polyester polyurethane, polyether polyresins, polyresins, polyester polyresins, polyisocyanurate, and polycarbodiimide.

In accordance with an exemplary embodiment, the adhesive can be ethylene/vinyl acetate copolymer (EVA).

Further exemplary embodiments can include glues that can be distinguished by high transmission in the spectrum range of current solar cells and by high UV stability, for example, when the glue also bonds the covering layer 4 to the solar cell 3.

In accordance with an exemplary embodiment, the covering layer 4 involves a layer made of a plastic, which can be distinguished by high transmission in the spectral range of current solar cells.

In accordance with another exemplary embodiment, the transmission of the covering-layer material, measured with a covering-layer thickness of approximately 0.1 mm in a spectrum of approximately 300 nm to 1300 nm, amounts to more than 85%, for example more than 90%, and for example more than 93%.

Suitable materials for the covering layer can be fluoropolymers such as copolymers of ethylene and tetrafluoroethylene, such as are sold, for example, by DuPont Corporation under the tradename of Tefzel®, or a polyvinylidene fluoride, sold by DuPont Corporation under the tradename of Tedlar®.

Such a covering layer can be advantageous in that it can protect the solar cell from damage and soil as well as penetration by liquid.

In accordance with an exemplary embodiment, the covering layer can exhibit a thickness of approximately 0.01 mm to 0.1 mm, for example, approximately 0.02 mm to 0.05 mm.

For example, the term “solar cell” in this disclosure can be understood to designate both an individual solar-cell unit and a plurality of solar-cell units connected electrically and/or mechanically. Such solar-cell units are, for example, commercially obtainable from Clean Venture 21, Japan; Fuji Electric, Japan; United Solar Ovonic LLC, USA; Helianthos BV, the Netherlands; VHF-Flexcell, Switzerland; and Ascent Solar, USA.

The term “solar-cell unit” in this disclosure can be understood to be a semiconductor component that contains a pn junction in which sunlight is converted directly into electrical energy, as is described in the CD Rompp Chemie Lexikon (1995), Georg Thieme Verlag: Stuttgart, Version 1.0.

In accordance with an exemplary embodiment, the carrier disclosed herein can include a flexible carrier made of plastic or metal, for example, made of corrosion-resistant steel or aluminum alloy.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### REFERENCE LIST

1 Module

2 Carrier

3 Solar cell

4 Covering layer

5 Side lugs

6 Corner lugs

7 Notches

8 Side edges

9 Fold line

10 Penetrating moisture

11 Point of contact of side edges

12 Distance

What is claimed is:

1. A module comprising:
a carrier;
at least one solar cell disposed on the carrier; and
a covering layer that is applied to a side of the at least one solar cell facing away from the carrier, wherein the covering layer includes side lugs, corner lugs, and notches, and wherein one notch forms a side edge of a side lug, another notch forms a side edge of a corner lug, and the side lugs and corner lugs are divided by a corresponding fold line and are disposed on a side of the carrier facing away from the at least one solar cell, and wherein the side edges of the side lugs and corner lugs formed by a notch are in contact with one another.

2. The module according to claim 1, wherein the side edges of the corner lugs overlap corresponding side edges of adjacent side lugs.

3. The module according to claim 1, wherein the side edges of the corner lugs overlap corresponding side edges of a total side edge of the side lugs.

4. The module according to claim 1, wherein the fold line of the corner lugs intersects the fold line of adjacent side lugs.

5. The module according to claim 1, wherein the fold line is at a location on the fold line of the side lugs, which is approximately 3 mm to 15 mm away, measured from a point of contact of the side edges of corresponding side lugs and corner lugs.

6. The module according to claim 1, wherein the fold line exhibits at least a distance of approximately 2 mm to 10 mm from the carrier.

7. The module according to claim 1, wherein the covering layer, the side lugs and the corner lugs are made from a same material.

8. A module comprising:
a carrier;
at least one solar cell arranged on the carrier;
a covering layer, having side lugs and corner lugs, which is provided on a side of the solar cell facing away from the carrier, and wherein the side lugs and the corner lugs include a notch on one side edge of a side lug or on one side edge of a corner lug, and wherein the side lugs and the corner lugs are separated by a fold line and disposed on a side of the carrier facing away from the at least one solar cell, and wherein sides edges of side lugs and corner lugs formed by a notch are in contact with one another; and
wherein the side lugs and the corner lugs are parts of the covering layer.

9. The module according to claim 8, wherein the notches are formed by removing or cutting out material during manufacturing of the covering layer.

10. The module according to claim 8, wherein the side edges of the corner lugs overlap the corresponding side edges of the adjacent side lugs.

11. The module according to claim 8, wherein the side edges of the corner lugs overlap corresponding side edges of a total side edge of the side lugs.

12. The module according to claim 8, wherein the fold line of the corner lugs intersects the fold line of the adjacent side lugs.

13. The module according to claim 8, wherein the fold line is at a location on the fold line of the side lugs is approximately 3 mm to 15 mm away, measured from the point of contact of the side edges of the corresponding side lugs and corner lugs.

14. The module according to claim 8, wherein the fold line exhibits at least a distance of approximately 2 mm to 10 mm from the carrier.

15. A method of covering at least one solar cell, comprising:
providing a carrier;
disposing at least one solar cell on the carrier; and
applying a covering layer to a side of the at least one solar cell facing away from the carrier, wherein the covering layer includes side lugs, corner lugs, and notches, and wherein one notch forms a side edge of a side lug, another notch forms a side edge of a corner lug, and the side lugs and corner lugs are divided by a corresponding fold line and are disposed on the side of the carrier facing away from the at least one solar cell, and wherein the side edges of the corresponding side lugs and corner lugs formed by a notch are in contact with one another.

16. The method according to claim 15, comprising:
overlapping the side edges of the corner lugs and corresponding side edges of adjacent side lugs.

17. The method according to claim 15, comprising:
locating the fold line of the side lugs at a location, which is approximately 3 mm to 15 mm away, measured from a point of contact of the side edges of corresponding side lugs and corner lugs.

18. The method according to claim 15, comprising:
providing at least a distance of approximately 2 mm to 10 mm from the fold lines to the carrier.

19. The method according to claim 15, comprising:
forming the notches by removing or cutting out material during manufacturing of the covering layer.
